(19) United States
(12) Patent Application Publication
(10) Pub. No.: US 2019/0217582 A1
(43) Pub. Date: Jul. 18, 2019

(54) METHOD OF MANUFACTURING HEAT RADIATION SHEET HAVING DOUBLE-LAYERED INSULATING STRUCTURE AND HEAT RADIATION SHEET USING THE SAME

(71) Applicant: WAPS. CO. LTD, Busan (KR)

(72) Inventors: Ju Hee SON, Busan (KR); Dae Hoon YEOM, Busan (KR); Si Young KIM, Yangsan-si, Gyeongsangnam-do (KR)

(73) Assignee: WAPS. CO. LTD, Busan (KR)

(21) Appl. No.: 15/579,371

(22) PCT Filed: Aug. 11, 2017
(86) PCT No.: PCT/KR2017/008749

§ 371 Date: Dec. 4, 2017

(30) Foreign Application Priority Data
Dec. 19, 2016 (KR) 10-2016-0173682

(51) Int. Cl. B32B 25/08; B32B 25/14; B32B 27/08; B32B 27/20; B32B 7/022; H05K 7/20; H05K 9/00

(52) U.S. Cl. CPC B32B 25/08; B32B 25/14; B32B 27/08; B32B 27/20; B32B 2307/3065; H05K 7/20481; H05K 9/0081; B32B 2270/00; B32B 2307/304; B32B 7/022

(57) ABSTRACT

A heat radiation sheet includes a low-hardness insulating heat-radiation layer and a high-heat-radiation insulating layer. Each of the low-hardness insulating heat-radiation layer and the high-heat-radiation insulating layer is formed by mixing a thermoplastic elastomer (TPE), a thermally conductive filler, a flame retardant additive, a process oil, and an additive. A method of manufacturing a heat radiation sheet having a double-layered insulating structure, includes: a first step of forming a mixture by mixing a thermoplastic elastomer (TPE), a thermally conductive filler, a flame retardant additive, a process oil, and an additive; a second step of melt-extruding the mixture at a temperature of 120 □ to 300 □ by a melt extrusion apparatus to from a melt extrudate; a third step of cutting the melt extrudate into a pellet form; and a fourth step of sheeting through melt-extruding the pellet into a sheet form by a melt extrusion apparatus.

### BACKGROUND OF THE INVENTION

### (a) Field of the Invention

Embodiments of the invention relate to a heat radiation sheet, and, more particularly, to a heat radiation sheet having a double-layered insulating structure including a low-hardness insulating heat-radiation layer and a high-heat-radiation insulating layer, thereby greatly reducing a thickness of a multi-layered heat radiation sheet and simplifying a manufacturing process.

### (b) Description of the Related Art

Recently, demands for high performance and miniaturization in electronic devices, such as, smart phones, displays, and portable computers, have been increased. Accordingly, a development of technologies for electronic components, such as, CPUs (central processing units), ICs (integrated circuits) is accelerated, thereby increasing a power consumption density and an amount of generated heat of the electronic components. A current technology development is in a situation where low power consumption may not catch up with high performance. High heat dissipation materials, low-power devices, and thermo-fluid analysis software for electronic devices are becoming major issues as a solution for solving thermal problems.

Conventionally, metals such as copper having a thermal conductivity of 350 to 400 W/mK and aluminum having a thermal conductivity of 220 to 250 W/mK have been used in order to efficiently eliminate heat. However, a sheet made of a metal such as copper or aluminum exhibits excellent properties in heat conduction, but has a poor adhesion property with a heat source and cannot effectively eliminate heat.

As the prior art for solving problems of the heat diffusion sheet, Japanese Laid-Open Patent Publication No. 10-2008-0076761 proposes a heat diffusion sheet including: a thermal conduction layer formed by a composition including a polymer and a thermally conductive filler; a thermal diffusion layer provided on a surface of the thermal conduction layer and formed of a metal material; and a heat insulating layer provided on a surface of the thermal diffusion layer and formed of an electrically insulating material. In addition, Korean Patent No. 10-1235541 proposes a multifunctional thin-film sheet including a heat-radiation and heat-diffusion layer formed of an inorganic material having a thermal conductivity, an electromagnetic-wave-shielding layer formed of a metal foil, and a polymer elastic cushion layer.

In the prior arts, in order to realize a thermal diffusion function, an electric insulation function, and an electromagnetic wave shielding function, the thermal diffusion sheet was formed by stacking layers having above respective functions. Thus, the thermal diffusion sheet has a multi-layered structure. Accordingly, there is a technical limitation that a thickness of the thermal diffusion sheet may be thicker beyond need and a structure and a manufacturing process of the thermal diffusion sheet are complicated.

Also, in view of reducing a thickness and a weight of a thermal diffusion sheet and simplifying a manufacturing process, it is required to provide a thermal diffusion sheet having a smaller number of layers that has an excellent electric insulation property and its outer shape is stably maintained. However, it has not been presented.

### SUMMARY OF THE INVENTION

Therefore, embodiments of the invention have been made in view of the above problems, and embodiments of the invention are to provide a method of manufacturing a heat radiation sheet being able to achieve both of an enhanced heat radiation property and an enhanced insulation property while reducing a thickness of the heat radiation sheet by omitting an adhesive layer.

Also, embodiment of the invention are also to provide a method of manufacturing a heat radiation sheet performed by an easy process through using a general processing method of a synthetic resin by using a thermoplastic elastomer (TPE) as a main raw material, thereby simplifying a manufacturing process.

Technical problems to be solved in the invention are not limited to the above. Thus, non-mentioned other technical problems to be solved will be understood by a skilled person in the art where the invention is pertained from the following description.

A heat radiation sheet according to an embodiment of the invention includes a low-hardness insulating heat-radiation layer 10 and a high-heat-radiation insulating layer 20. Each of the low-hardness insulating heat-radiation layer 10 and the high-heat-radiation insulating layer 20 may be formed by mixing a thermoplastic elastomer (TPE), a thermally conductive filler, a flame retardant additive, a process oil, and an additive.

Also, a method of manufacturing a heat radiation sheet having a double-layered insulating structure includes: a first step of forming a mixture by mixing a thermoplastic elastomer (TPE), a thermally conductive filler, a flame retardant additive, a process oil, and an additive; a second step of melt-extruding the mixture at a temperature of 120 □ to 300 □ by a melt extrusion apparatus to from a melt extrudate; a third step of cutting the melt extrudate into a pellet form; and a fourth step of sheeting through melt-extruding the pellet into a sheet form by a melt extrusion apparatus;

According to embodiments of the invention, a heat radiation sheet having both an enhanced heat radiation property and an enhanced insulation property can be manufactured.

Also, according to embodiments of the invention, a heat radiation sheet having a small thickness can be manufactured because the heat radiation sheet does not include an adhesive layer.

Further, according to embodiments of the invention, a heat radiation sheet can be formed by an easy process through using a general processing method of a synthetic resin by using a thermoplastic elastomer (TPE) as a main raw material, and thus, a manufacturing process can be simplified.

### BRIEF DESCRIPTION OF THE DRAWINGS

FIG. 1 is a schematic view of a heat radiation sheet having a double-layered insulating structure according to an embodiment of the invention.

FIG. 2 is a flowchart showing a method of manufacturing a heat radiation sheet having a double-layered insulating structure.

### DETAILED DESCRIPTION OF THE EMBODIMENTS

Embodiments of the invention relate to a heat radiation sheet, and, more particularly, to a heat radiation sheet having a double-layered insulating structure including a low-hardness insulating heat-radiation layer 10 and a high-heat-radiation insulating layer 20 to have a greatly small thickness and formed by a simplified manufacturing process.

The above and other objects, features, and advantages of the invention will be included in the following description and the accompanying drawings. The advantages and features of the invention, and how to accomplish them, will become apparent by reference to an embodiment which will be described in detail below with reference to the accompanying drawings.

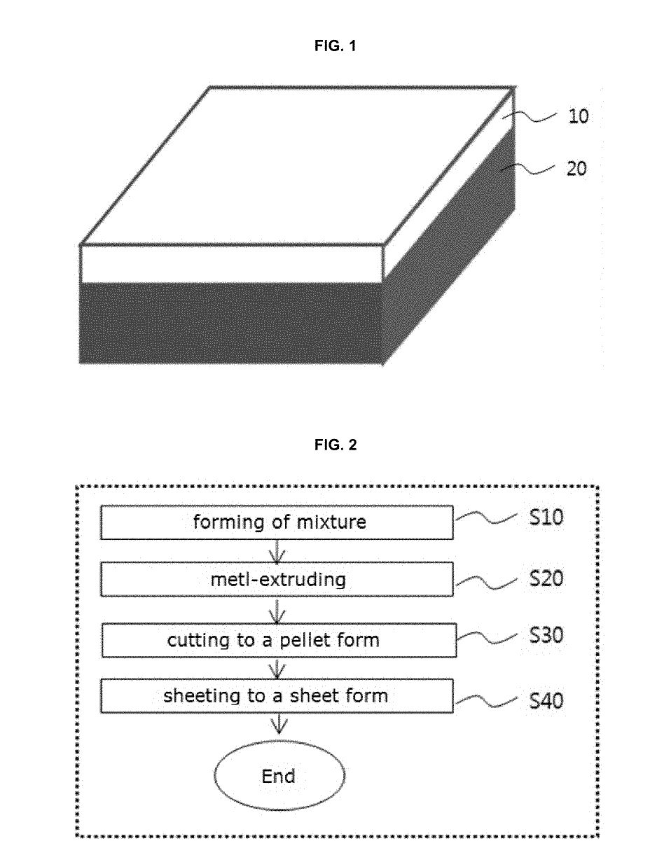

Hereinafter, a heat radiation sheet having a double-layered insulating structure will be described in detail with reference to the accompanying drawings. FIG. 1 is a schematic view of a heat radiation sheet having a double-layered insulating structure according to an embodiment of the invention.

A heat radiation sheet having a double-layered insulating structure according to an embodiment of the invention includes a low-hardness insulating heat-radiation layer 10 and a high-heat-radiation insulating layer 20. The low-hardness insulating heat-radiation layer 10 may be disposed at a lower portion and the high-heat-radiation insulating layer 20 may be sequentially stacked on an upper portion of the low hardness insulating layer 10. The low-hardness insulating heat-radiation layer 10 may be disposed to be contact with a heat source.

The low-hardness insulating heat-radiation layer may have a Shore A hardness of 30 or less, a thermal conductivity of 0.4 to 3 W/m·K, a UL94 flammability of V-0, and an insulation breakdown voltage of 5 to 30 kV/mm.

If the Shore A hardness of the low-hardness insulating heat-radiation layer 10 exceeds 30, a contact with the heat source may be not good and it may be difficult to effectively eliminate the heat. If the thermal conductivity of the low-hardness insulating heat-radiation layer 10 is less than 0.4 W/m·K, the thermal conductivity may be too low and the heat of the heat source may be not released well. In addition, since the heat radiation sheet is generally used together with electronic products, a flame retardant property is required. If the insulation breakdown voltage of the low-hardness insulating heat-radiation layer 10 is less than 5 kV/mm, electric current may flow and it may induce a break of an electronic product.

The high-heat-radiation insulating layer 20 may have a Shore A hardness of 70 or less, a thermal conductivity of 1.1 to 5 W/m·K, a UL94 flammability of V-0, an insulation breakdown voltage of 5 to 30 kV/mm.

If the Shore A hardness of the high-heat-radiation insulating layer 20 exceeds 70, it may affect a contact between the low-hardness insulating heat-radiation layer 10 and the heat source, the contact between the low-hardness insulating heat-radiation layer 10 and the heat source may be not good, and thus, the heat may not be effectively eliminated. If the thermal conductivity of the high-heat-radiation insulating layer 20 is less than 1.1 W/m·K, the thermal conductivity may be too low and the heat of the heat source may be not released well. In addition, since the heat radiation sheet is generally used together with electronic products, a flame retardant property is required.

Each of the low-hardness insulating heat-radiation layer 10 and the high-heat-radiation insulating layer 20 may be manufactured to include a thermoplastic elastomer (TPE), a thermally conductive filler, a flame retardant additive, a process oil, and an additive.

At least one (for example, each) of the low-hardness insulating heat-radiation layer 10 and the high-heat-radiation insulating layer 20 may be manufactured to further include a rubber to increase a surface adhesion force.

More particularly, each of the low-hardness insulating heat-radiation layer 10 and the high-heat-radiation insulating layer 20 may be manufactured by mixing 30 to 800 parts by weight of the thermally conductive filler, 30 to 800 parts by weight of the flame retardant additive, 80 to 200 parts by weight of the process oil, and 0.1 to 10 parts by weight of the additive, based on 100 parts by weight of the thermoplastic elastomer (TPE).

In addition, as necessary, at least one (for example, each) of the low-hardness insulating heat-radiation layer 10 and the high-heat-radiation insulating layer 20 may be manufactured by additionally adding 5 to 200 parts by weight of the rubber, based on 100 parts by weight of the thermoplastic elastomer (TPE).

First, the thermoplastic elastomer (TPE) is an elastic material which has elasticity and is molten when heat is applied and then is processed into a predetermined shape, like a thermosetting elastomer. The thermoplastic elastomer (TPE) has an elastic body of a rubber, while a general processing method of a synthetic resin may be used for the thermoplastic elastomer (TPE).

Any thermoplastic elastomer (TPE) may be used. In order to maximize an effect of the invention, at least one of a styrene-ethylene-butylene-styrene (SEBS) block copolymer, a styrene-ethylene-propylene-styrene (SEPS) block copolymer, a styrene-ethylene-ethylene-propylene-styrene (SEEPS) block copolymer, a polypropylene, a polyethylene, a polyisobutylene, and an alpha olefin resin may be used. More particularly, a styrene-ethylene-butylene-styrene (SEBS) block copolymer may be the most effective.

Next, the thermally conductive filler may be attached to an object to be heat-dissipated via a heat-transfer material, and may allow the heat generated by the object to be easily transferred to another layer.

The thermally conductive filler may include at least one of carbon black, carbon nanotube, graphite, alumina, aluminum hydroxide, aluminum nitride, boron nitride, and a ceramic-carbon complex.

The carbon black, the carbon nanotube, and the graphite are carbon-based fillers which are light and have an excellent thermal conductivity.

Also, the alumina, the aluminum hydroxide, the aluminum nitride, the boron nitride, and the ceramic-carbon complex are ceramic-based fillers, which have an excellent electrical insulation property.

In particular, since the ceramic-carbon complex has an excellent thermal conductivity and an excellent electrical insulation property, the ceramic-carbon complex may be used for the high-heat-radiation insulating layer 20, and may not be used for the how-hardness insulating heat-radiation layer 10.

The thermally conductive filler may be included in an amount of 30 to 800 parts by weight, more particularly, 50 to 600 parts by weight, based on 100 parts by weight of the thermoplastic elastomer (TPE). If the thermally conductive filler is included less than 30 parts by weight, the thermal conductivity may be significantly lowered, and heat may be difficult to be transferred in fact. If the thermally conductive filler is included greater than 800 parts by weight, a mechanical property may be significantly lowered or an insulation breakdown voltage may be lowered. Therefore, the thermally conductive filler may be included in the amount of the above range.

Next, the flame retardant additive may be used to ensure the highest level of flammability without deteriorating properties of the composition. Here, the flame retardant additive may be formed of a nitrogen-based flame retardant, a metal hydroxide, and a phosphorus-based flame retardant, and two of these may be used in combination.

According to a result of several experiments, in order to maximize effects of the embodiment of the invention, the nitrogen-based flame retardant may include at least one of ammonium phosphate, ammonium carbonate, a triazine compound, melamine cyanurate, or a guanidine compound, and the metal hydroxide may include magnesium hydroxide, and the phosphorus-based flame retardant may include at least one of melamine polyphosphate, ammonium polyphosphate, diammonium phosphate, monoammonium phosphate, polyphosphoric acid amide, phosphoric acid amide, melamine phosphate, and red phosphate.

Also, the flame retardant additive may be included by 30 to 800 parts by weight, more particularly, 50 to 600 parts by weight, based on 100 parts by weight of the thermoplastic elastomer (TPE). If an amount of the flame retardant is less than 30 parts by weight, the flammability may be significantly lowered, and the flammability may be in fact difficult to be exhibited. When an amount of the flame retardant is more than 800 parts by weight, mechanical properties of the composition may be remarkably deteriorated.

Next, the process oil provides liquidity or fluidity to the composition.

The process oil may include at least one of paraffin-based oil and naphthen-based oil. More particularly, when the paraffin-based oil is used, it is most effective in improving the fluidity and preventing the deterioration of flammability in embodiments of the invention.

The process oil may have a kinematic viscosity of 95 to 120 cSt at 40 □ and a flash point of 220 to 300 □. More particularly, the process oil may have a kinematic viscosity of 110 to 120 cSt at 40 □ and a flash point of 250 to 270 ⊐. If they are not within the ranges, sufficient fluidity may be not achieved, or physical properties and flammability may be deteriorated.

The process oil may be included in an amount of 80 to 200 parts by weight, more particularly, 100 to 180 parts by weight, based on 100 parts by weight of the thermoplastic elastomer (TPE). If the amount of the process oil is less than 80 parts by weight, a hardness of the composition may increase and a fluidity of the composition may be deteriorated, thereby causing a problem in processing. If the amount of the process oil is more than 200 parts by weight, a hardness may be too low, mechanical properties may be significantly deteriorated, and a flammability may be in fact difficult to be exhibited.

Next, the additive may include at least one selected from a heat stabilizer, an antioxidant, a ultraviolet (UV) stabilizer, a lubricant, and a coupling agent. The heat radiation sheet having the double-layered insulating structure according to the embodiment of the invention may include an additive, together with the thermoplastic elastomer (TPE), to assist to improve a flammability and to enhance a durability as a whole.

More particularly, the heat stabilizer and the UV stabilizer not only contribute to an improvement of a flammability but also improve an overall durability. The antioxidant also improves the durability through inhibiting an oxidation. A pigment implements a proper color according to a use or a purpose of the composition.

The additive may be included in an amount of 0.1 to 10 parts by weight, more particularly, 0.5 to 5 parts by weight, based on 100 parts by weight of the thermoplastic elastomer (TPE). If the amount of the additive is less than 0.1 part by weight, effects due to the additive may be not sufficient. If the amount of the additive is more than 10 parts by weight, properties of the composition may be deteriorated.

As described above, in the embodiment of the invention, each of the low-hardness insulating heat-radiation layer 10 and the high-heat-radiation insulating layer 20 may be basically manufactured by mixing 30 to 800 parts by weight of the thermally conductive filler, 30 to 800 parts by weight of the flame retardant additive, 80 to 200 parts by weight of the process oil, and 0.1 to 10 parts by weight of the additive, based on 100 parts by weight of the thermoplastic elastomer (TPE). The rubber may be additionally used in order to a surface adhesion force.

The rubber may include at least one of an isoprene rubber (IR), a butadiene rubber (BR), a styrene-butadiene rubber (SBR), a polychloroprene rubber (CR), an acrylonitrile-butadiene rubber (NBR), an isoprene-isobutadiene rubber (IIR), an ethylene-propylene rubber (EPR), a silicone rubber, a fluoro rubber, a urethane rubber, and an acrylic rubber.

The rubber may be included in an amount of 5 to 200 parts by weight, more particularly, 30 to 100 parts by weight, based on 100 parts by weight of the thermoplastic elastomer (TPE).

If the rubber is included less than 5 parts by weight based on 100 parts by weight of the thermoplastic elastomer (TPE), an amount of the rubber may be low and an effect of increasing the surface adhesion force may be not sufficient. When the rubber is included more than 200 parts by weight based on 100 parts by weight of the thermoplastic elastomer (TPE), a heat radiation effect may be lowered. Thus, the amount of the rubber may be in the above range.

FIG. 2 is a flowchart showing a method of manufacturing a heat radiation sheet having a double-layered insulating structure.

First, in a first step (S10), a mixture is formed by mixing a thermoplastic elastomer (TPE), a thermally conductive filler, a flame retardant additive, a process oil, and an additive.

Particularly, in the mixing step (S10), each of the low-hardness insulating heat-radiation layer 10 and the high-heat-radiation insulating layer 20 is formed by mixing 30 to 800 parts by weight of a thermally conductive filler, 30 to 800 parts by weight of a flame retardant additive, 80 to 200 parts by weight of a process oil, and 0.1 to 10 parts by weight of an additive, based on 100 parts by weight of the thermoplastic elastomer (TPE). The low-hardness insulating heat-radiation layer 10 may be mixed to have a Shore A hardness of 30 or less, a thermal conductivity of 0.4 to 3 W/m·K, a UL94 flammability of V-0, and an insulation breakdown voltage of 5 to 30 kV/mm. The high-heat-radiation insulating layer 20 may be mixed to have a Shore A hardness of 70 or less, a thermal conductivity of 1.1 to 5 W/m·K, a UL94 flammability of V-0, an insulation breakdown voltage of 5 to 30 kV/mm.

Any material may be used for the thermoplastic elastomer. However, in order to maximize the effect of embodiments of the invention, the thermoplastic elastomer may include at least one of a styrene-ethylene-butylene-styrene (SEBS) block copolymer, a styrene-ethylene-propylene-styrene (SEPS) block copolymer, a styrene-ethylene-ethylene-propylene-styrene (SEEPS) block copolymer, polypropylene, polyethylene, polyisobutylene, and an alpha olefin resin. More particularly, a styrene-ethylene-butylene-styrene (SEBS) block copolymer is most effective.

The thermally conductive filler may include at least one of carbon black, carbon nanotubes, graphite, alumina, aluminum hydroxide, aluminum nitride, boron nitride, and a ceramic-carbon complex. The ceramic-carbon complex may be selectively mixed to or included in only the high-heat-radiation insulating layer 20.

The flame retardant additive may include at least one of a nitrogen-based flame retardant, a metal hydroxide, and a phosphorus-based flame retardant. The nitrogen-based flame retardant may include at least one selected from ammonium phosphate, ammonium carbonate, a triazine compound, melamine cyanurate, or a guanidine compound, the metal hydroxide may include at least one selected from aluminum hydroxide and magnesium hydroxide, and the phosphorus-based flame retardant may include at least one selected from organic phosphorus-based compounds including phosphate.

The process oil may include at least one of a paraffin-based oil and a naphthen-based oil, more particularly, a paraffin-based oil.

The additive may include at least one selected from a heat stabilizer, an antioxidant, a ultraviolet (UV) stabilizer, a lubricant, and a coupling agent.

The rubber used to additionally increase a surface adhesion force may include at least one selected from an isoprene rubber (IR), a butadiene rubber (BR), a styrene-butadiene rubber (SBR), a polychloroprene rubber (CR), an acrylonitrile-butadiene rubber (NBR), an isoprene-isobutylene rubber (IIR), an ethylene-propylene rubber (EPR), a silicone rubber, a fluoro rubber, a urethane rubber, and an acrylic rubber.

Next, in the second step (S20), the mixture is melt-extruded at 120 ⊐ to 300 □ to form a melt extrudate by a melt extrusion apparatus.

If the mixture is melt-extruded at a temperature lower than 120 □, the mixture may be difficult to be molten and the mixing may be not smoothly performed. If the mixture is melt-extruded at a temperature higher than 300 □, a resin may be decomposed and thus desirable properties may not achieved. Thus, the temperature of the melt extrusion may be in the above range.

Next, in the third step (S30), the melt extrudate is cut into a pellet form.

When the melt extrudate is cut into the pellet form, it is easy to be packed and is transported, and a machining or a process of the melt extrudate in a next process may be easy.

More particularly, the pellet form may have a size of 0.1 mm to 20 mm. If the pellet form has a size less than 0.1 mm, the pellet form may not be formed or maintained well. If the pellet form has a size greater than 20 mm, a machining or a processing of the melt extrudate in a next process may be not easy. Thus, the size of the pellet form may be in the above range.

Next, in the fourth step (S40), the pellet is melt-extruded into a sheet formed through a sheeting process by a melt extrusion apparatus.

The sheeting step S40 may include independently or separately sheeting or forming of the low-hardness insulating heat-radiation layer 10 and the high-heat-radiation insulating layer 20, and hot-pressing of the low-hardness insulating heat-radiation layer 10 and the high-heat-radiation insulating layer 20 to form a sheet. Alternatively, the sheeting step S40 may include forming of a sheet including the low-hardness insulating heat-radiation layer 10 and the high-heat-radiation insulating layer 20 at one time by a co-extrusion apparatus.

When the sheeting step S40 includes independently or separately sheeting or forming of the low-hardness insulating heat-radiation layer 10 and the high-heat-radiation insulating layer 20 and hot-pressing of the low-hardness insulating heat-radiation layer 10 and the high-heat-radiation insulating layer 20 to form a sheet, an additional co-extrusion apparatus is not necessary.

Also, the sheeting step S40 includes forming of the sheet including the low-hardness insulating heat-radiation layer 10 and the high-heat-radiation insulating layer 20 at one time by the co-extrusion apparatus, a process step can be minimized.

Hereinafter, properties of a heat radiation sheet having a double-layered insulating structure according to an embodiment of the invention will be described with reference to Embodiments and Comparative Examples.

A hardness, a flammability, a thermal conductivity, and an insulation breakdown voltages of a heat radiation sheet manufactured according to the invention were measured. In the experiment, properties of a specimen are evaluated as follows:

(1) Hardness: A hardness of a specimen having a thickness of 3 mm was measured in accordance with an ASTM D 2240 method.

(2) Flammability: A flammability of a specimen having a thickness of 2 mm was measured in accordance with a UL94 VB method.

(3) Thermal Conductivity: Two kinds of 8T specimens were prepared and thermal conductivities thereof were measured in accordance with an ISO standard 22007-2 method.

(4) Insulation Breakdown Voltage: An insulating breakdown voltage of a specimen having a thickness of 2 mm was measured in accordance with an ASTM D 149 method.

A. Low-hardness Insulating Heat-radiation Layer 10

The following Table 1 shows a measured result of a hardness, a flammability, a thermal conductivity, and an insulating breakdown voltage of each of specimens having compositions of low-hardness insulating heat-radiation layers 10 manufactured according to the invention (Embodiments 1 to 3) and specimens having compositions of low-hardness insulating heat-radiation layers 10 that are beyond a range of the invention (Comparative Examples 1 and 2), according to an amount (for example, in weight) of each material.

TABLE 1

| | | Embodiment | Embodiment | Embodiment | Comparative | Comparative |
|---|---|---|---|---|---|---|
| | | 1 | 2 | 3 | Example 1 | Example 2 |
| TPE | SEBS | 100 | 100 | 100 | 100 | 100 |
| Rubber | SBR | — | — | 300 | — | — |
| Thermally | Graphite | — | — | — | 200 | — |
| Conductivity | Alumina | 100 | — | — | — | 700 |
| Filler | Aluminum | 300 | 400 | 400 | — | — |
| | Hydroxide | | | | | |
| Flame | Organic | 20 | 30 | 30 | — | — |
| Retardant | Phosphorus | | | | | |
| Additive | Compound | | | | | |
| Process Oil | | 100 | 100 | 100 | 100 | 100 |
| Additive | Anti- | 0.1 | 0.1 | 0.1 | 0.1 | 0.1 |
| | oxidant | | | | | |
| | Lubicant | 0.1 | 8 | 8 | 0.1 | 0.1 |

| | | | | | |
|---|---|---|---|---|---|
| Result | | | | | |
| Hardness | 25 | 30 | 23 | 45 | 33 |
| (Shore A) | | | | | |
| Flammability Grade | V-1 | V-0 | V-0 | NG | NG |
| (UL94, 2 mm) | | | | | |
| Thermal Conductivity | 0.6 | 0.5 | 0.5 | 1.5 | 0.7 |
| (W/m · K) | | | | | |
| Insulation Breakdown | 18 | 19 | 20 | 0.2 | 15 |
| Voltage (kV/mm) | | | | | |
| Surface Adhesion Property | ◯ | ◯ | ⊚ | Δ | ◯ |

As shown in Table 1, in Embodiment 1 of the low-hardness insulating heat-radiation layer 10 that was manufactured according to a mixing ratio of the invention, a styrene-ethylene-butylene-styrene (SEBS) block copolymer was used for a thermoplastic elastomer, and alumina and aluminum hydroxide were used for a thermally conductive filler. Also, an organic phosphorus compound was used for a flame retardant additive, and an antioxidant and a lubricant were mixed and used for an additive.

In the case of the low-hardness insulating heat-radiation layer 10 manufactured by the manufacturing method of Embodiment 1, the Shore A hardness was 25, the flammability grade was V-1, the thermal conductivity was 0.6 W/m·K, the insulation breakdown voltage was 18 kV/mm. In the case of Embodiment 1, it can be seen that the insulation breakdown voltage is very high, and also, the flammability grade and the thermal conductivity was excellent and the hardness was suitable to be used for the low-hardness insulating heat-radiation layer 10, which are very effective as the low-hardness insulating heat-radiation layer 10 of the heat radiation sheet.

Also, in Embodiment 2, a styrene-ethylene-butylene-styrene (SEBS) block copolymer was used for a thermoplastic elastomer, and aluminum hydroxide was used for a thermally conductive filler. Also, an organic phosphorus compound was used for a flame retardant additive, and an antioxidant and a lubricant were mixed and used for an additive.

In the case of the low-hardness insulating heat-radiation layer 10 manufactured by the manufacturing method of Embodiment 2, the Shore A hardness was 30, the flammability grade was V-0, the thermal conductivity was 0.5 W/m·K, the insulation breakdown voltage was 19 kV/mm. In the case of Embodiment 2, it can be seen that the insulation break voltage was very high and the flammability grade was excellent even though the hardness is slightly greater than that in Embodiment 1. Also, the thermal conductivity was very high, and thus, it can be seen that the layer according to Embodiment 1 is very effective as the low-hardness insulating heat-radiation layer 10 of the heat radiation sheet.

Also, in Embodiment 3, a styrene-ethylene-butylene-styrene (SEBS) block copolymer was used for a thermoplastic elastomer, and aluminum hydroxide was used for a thermally conductive filler. Also, an organic phosphorus compound was used for a flame retardant additive, an antioxidant and a lubricant were mixed and used for an additive, and a styrene-butadiene rubber (SBR) was used for a rubber.

In the case of the low-hardness insulating heat-radiation layer 10 manufactured by the manufacturing method of Embodiment 3, the Shore A hardness was 23, the flammability grade was V-0, the thermal conductivity was 0.5 W/m·K, the insulation breakdown voltage was 20 kV/mm. In the case of Embodiment 3, it can be seen that the hardness is less than that in the Embodiment 2, the insulation break voltage was high, and the surface adhesion property was excellent. Also, the flammability grade was high and the thermal conductivity was high. Thus, it can be seen that the layer according to Embodiment 1 is very effective as the low-hardness insulating heat-radiation layer 10 of the heat radiation sheet.

On the other hand, in the case of Comparative Example 1, graphite, which is a carbon-based thermally conductive filler, was used, but no flammability was exhibited at all, and the insulation breakdown voltage was 0.2 kV/mm and the insulation property was not exhibited at all. In addition, since the Shore A hardness was very high as 45. Thus, it can be seen that the layer according to Comparative Example 1 is difficult to be used for the low-hardness insulating heat-radiation layer 10 of the heat radiation sheet.

Also, in the case of Comparative Example 2, alumina was used for a thermally conductive filler and thus the thermal conductivity and the insulating breakdown voltage of desired properties are achieved, but no flammability was obtained. Also, the Shore A hardness was very high as 33. Thus, it can be seen that the layer according to Comparative Example 2 is difficult to be used for the low-hardness insulating heat-radiation layer 10 of the heat radiation sheet.

B. High-heat-radiation Insulating Layer 20

The following Table 2 shows a measured result of a hardness, a flammability, a thermal conductivity, and an insulating breakdown voltage of each of specimens having compositions of high-heat-radiation insulating layers 20 manufactured according to the invention (Embodiments 1 and 2) and specimens having compositions of high-heat-radiation insulating layers 20 that are beyond the range of the invention (Comparative Examples 1 to 3), according to an amount (for example, in weight) of each material.

TABLE 2

| | | Embodiment | Embodiment | Comparative | Comparative | Comparative |
|---|---|---|---|---|---|---|
| | | 1 | 2 | Example 1 | Example 2 | Example 3 |
| TPE | SEBS | 100 | 100 | 100 | 100 | 100 |
| Thermally | Graphite | — | — | 300 | — | — |
| Conductivity | Alumina | — | 100 | — | — | 250 |
| Filler | Aluminum | 250 | 200 | 200 | 500 | 250 |
| | Hydroxide | | | | | |
| | Ceramic- | 250 | 200 | — | — | — |
| | Carbon | | | | | |
| | Composite | | | | | |
| Flame | Organic | 20 | 30 | 30 | — | — |
| Retardant | Phosphorus | | | | | |
| Additive | Compound | | | | | |
| Process Oil | | 100 | 100 | 100 | 100 | 100 |
| Additive | Anti- | 0.1 | 0.1 | 0.1 | 0.1 | 0.1 |
| | oxidant | | | | | |
| | Lubicant | 0.1 | 8 | 0.1 | 0.1 | 0.1 |

| | | | | | |
|---|---|---|---|---|---|
| Result | | | | | |
| Hardness | 43 | 48 | 50 | 30 | 40 |
| (Shore A) | | | | | |
| Flammability Grade | V-0 | V-0 | V-0 | V-0 | V-1 |
| (UL94, 2 mm) | | | | | |
| Thermal Conductivity | 1.3 | 1.2 | 1.6 | 0.5 | 0.6 |
| (W/m · K) | | | | | |
| Insulation Breakdown | 5.5 | 6 | 0.1 | 15 | 18 |
| Voltage (kV/mm) | | | | | |

As shown in Table 2, in Embodiment 1 of the high-radiation insulating layer 20 that was manufactured according to a mixing ratio of the invention, a styrene-ethylene-butylene-styrene (SEBS) block copolymer was used for a thermoplastic elastomer, and a ceramic-carbon compound with alumina and aluminum hydroxide were used for a thermally conductive filler. Also, an organic phosphorus compound was used for a flame retardant additive, and an antioxidant and a lubricant were mixed and used for an additive.

In the case of the high-heat-radiation insulating layer 20 manufactured by the manufacturing method of Embodiment 1, the Shore A hardness was 43, the flammability grade was V-0, the thermal conductivity was 1.3 W/m·K, the insulation breakdown voltage was 5.5 kV/mm. In the case of Embodiment 1, it can be seen that the flammability grade and the thermal conductivity were excellent and the hardness was suitable to be used for the high-heat-radiation insulating layer 20, which are very effective as the high-heat-radiation insulating layer 20 of the heat radiation sheet.

Also, in Embodiment 2, a styrene-ethylene-butylene-styrene (SEBS) block copolymer was used for a thermoplastic elastomer, and graphite and aluminum hydroxide was mixed and used for a thermally conductive filler. Also, an organic phosphorus compound was used for a flame retardant additive, and an antioxidant and a lubricant were mixed and used for an additive.

In the case of the high-heat-radiation insulating layer 20 manufactured by the manufacturing method of Embodiment 2, the Shore A hardness was 48, and thus, it can be seen that the layer according Embodiment 2 has the hardness to be easily manufactured to form the heat radiation sheet. Also, the flammability grade was V-0, the thermal conductivity was 1.2 W/m·K, the insulation breakdown voltage was 6 kV/mm. In the case of Embodiment 2, it can be seen that the insulation break voltage was very high, the flammability grade and the thermal conductivity were excellent, and the hardness was suitable to be used for the high-heat-radiation insulating layer 20, as in Embodiment 1. Thus, it can be seen that the layer according to Embodiment 2 is very effective as the high-heat-radiation insulating layer 20 of the heat radiation sheet.

On the other hand, in the case of Comparative Example 1, graphite, which is a carbon-based thermally conductive filler, was used. However, since a carbon-silica composite was not mixed, which is different from Embodiments 1 and 2 of the invention, the insulation breakdown voltage was very low as 0.1 kV/mm. Thus, it can be seen that the layer according to Comparative Example 1 is difficult to be used for the high-heat-radiation insulating layer 20 of the heat radiation sheet.

Also, in the case of Comparative Example 2, aluminum hydroxide was used for a flame retardant additive and thus the flammability was achieved, but the thermal conductive was very low as 0.5 kV/mm. Thus, it can be seen that the layer according to Comparative Example 2 is difficult to be used for the high-heat-radiation insulating layer 20 of the heat radiation sheet.

Also, in the case of Comparative Example 3 alumina was used for a thermally conductive filler and aluminum hydroxide was used for a flame retardant additive and thus the flammability was achieved to some degree, but the thermal conductive was very low as in Comparative Example 2. Thus, it can be seen that the layer according to Comparative Example 3 is difficult to be used for the high-heat-radiation insulating layer 20 of the heat radiation sheet.

It will be understood that embodiments of the invention may be embodied by other technical modifications without departing from the technical spirit or essential characteristics of the invention by those skilled in the art.

The above-described features, structures, effects, and the like are included in at least one embodiment of the invention, and are not necessarily limited to only one embodiment. Further, the features, structures, effects and the like illustrated in the embodiments may be combined and modified by persons skilled in the art to which the embodiments are pertained. Therefore, it is to be understood that embodiments of the invention are not limited to these embodiments, and various combined and modified embodiments are included in a scope of the invention.

1. A heat radiation sheet having a double-layered insulating structure, comprising:
a low-hardness insulating heat-radiation layer; and
a high-heat-radiation insulating layer,
wherein each of the low-hardness insulating heat-radiation layer and the high-heat-radiation insulating layer comprises a thermoplastic elastomer (TPE), a thermally conductive filler, a flame retardant additive, a process oil, and an additive, wherein the low-hardness insulating heat-radiation layer has a Shore A hardness of 30 or less, a thermal conductivity of 0.4 to 3 W/m·K, a UL94 flammability of V-0, and an insulation breakdown voltage of 5 to 30 kV/mm, wherein the high-heat-radiation insulating layer has a Shore A hardness of 70 or less, a thermal conductivity of 1.1 to 5 W/m·K, a UL94 flammability of V-0, an insulation breakdown voltage of 5 to 30 kV/mm,
wherein the thermoplastic elastomer (TPE) includes at least one of a styrene-ethylene-butylene-styrene (SEBS) block copolymer, a styrene-ethylene-propylene-styrene (SEPS) block copolymer, a styrene-ethylene-ethylene-propylene-styrene (SEEPS) block copolymer, polypropylene, polyethylene, polyisobutylene, and an alpha olefin resin,
wherein the flame retardant additive includes at least one of a nitrogen-based flame retardant, a metal hydroxide, and a phosphorus-based flame retardant, and
wherein the additive includes at least one of a heat stabilizer, an antioxidant, a ultraviolet (UV) stabilizer, a lubricant, and a coupling agent.

2. The heat radiation sheet having the double-layered insulating structure according to claim 1, wherein each of the low-hardness insulating heat-radiation layer and the high-heat-radiation insulating layer comprises 30 to 800 parts by weight of the thermally conductive filler, 30 to 800 parts by weight of the flame retardant additive, 80 to 200 parts by weight of the process oil, and 0.1 to 10 parts by weight of the additive, based on 100 parts by weight of the thermoplastic elastomer (TPE).

3. The heat radiation sheet having the double-layered insulating structure according to claim 1, wherein each of the low-hardness insulating heat-radiation layer and the high-heat-radiation insulating layer further comprises a rubber,
wherein the rubber comprises at least one of an isoprene rubber (IR), a butadiene rubber (BR), a styrene-butadiene rubber (SBR), a polychloroprene rubber (CR), an acrylonitrile-butadiene rubber (NBR), an isoprene-isobutylene rubber (IIR), an ethylene-propylene rubber (EPR), a silicone rubber, a fluoro rubber, a urethane rubber, and an acrylic rubber, and
wherein the rubber is included in an amount of 5 to 200 parts by weight, based on 100 parts by weight of the thermoplastic elastomer (TPE).

4. The heat radiation sheet having the double-layered insulating structure according to claim 1, wherein the nitrogen-based flame retardant comprises at least one selected from ammonium phosphate, ammonium carbonate, a triazine compound, melamine cyanurate, and a guanidine compound,
wherein the metal hydroxide comprises at least one selected from aluminum hydroxide and magnesium hydroxide, and
wherein the phosphorus-based flame retardant comprises at least one selected from organic phosphorus-based compounds including phosphate.

5. The heat radiation sheet having the double-layered insulating structure according to claim 1, wherein the thermally conductive filler of the low-hardness insulating heat-radiation layer comprises at least one of carbon black, carbon nanotube, graphite, alumina, aluminum hydroxide, aluminum nitride, and boron nitride.

6. The heat radiation sheet having the double-layered insulating structure according to claim 1, wherein the thermally conductive filler of the high-heat-radiation insulating layer comprises at least one of carbon black, carbon nanotube, graphite, alumina, aluminum hydroxide, aluminum nitride, boron nitride, and a ceramic-carbon complex.

7. The heat radiation sheet having the double-layered insulating structure according to claim 1, wherein the process oil comprises at least one of a paraffin-based oil and a naphthen-based oil, and
wherein the process oil has a kinematic viscosity of 95 to 120 cSt at 40° C. and a flash point of 220 to 300° C.

8. A method of manufacturing a heat radiation sheet having a double-layered insulating structure, comprising:
a first step of forming a mixture by mixing a thermoplastic elastomer (TPE), a thermally conductive filler, a flame retardant additive, a process oil, and an additive;
a second step of melt-extruding the mixture at a temperature of 120° C. to 300° C. by a melt extrusion apparatus to from a melt extrudate;
a third step of cutting the melt extrudate into a pellet form; and
a fourth step of sheeting through melt-extruding the pellet into a sheet form by a melt extrusion apparatus;
wherein the low-hardness insulating heat-radiation layer has a Shore A hardness of 30 or less, a thermal conductivity of 0.4 to 3 W/m·K, a UL94 flammability of V-0, and an insulation breakdown voltage of 5 to 30 kV/mm, wherein the high-heat-radiation insulating layer has a Shore A hardness of 70 or less, a thermal conductivity of 1.1 to 5 W/m·K, a UL94 flammability of V-0, an insulation breakdown voltage of 5 to 30 kV/mm,
wherein the thermoplastic elastomer (TPE) includes at least one of a styrene-ethylene-butylene-styrene (SEBS) block copolymer, a styrene-ethylene-propylene-styrene (SEPS) block copolymer, a styrene-ethylene-ethylene-propylene-styrene (SEEPS) block copolymer, polypropylene, polyethylene, polyisobutylene, and an alpha olefin resin,
wherein the flame retardant additive includes at least one of a nitrogen-based flame retardant, a metal hydroxide, and a phosphorus-based flame retardant, and
wherein the additive includes at least one of a heat stabilizer, an antioxidant, a ultraviolet (UV) stabilizer, a lubricant, and a coupling agent.

9. The method according to claim 8, wherein each of the low-hardness insulating heat-radiation layer and the high-heat-radiation insulating layer comprises 30 to 800 parts by weight of the thermally conductive filler, 30 to 800 parts by weight of the flame retardant additive, 80 to 200 parts by weight of the process oil, and 0.1 to 10 parts by weight of the additive, based on 100 parts by weight of the thermoplastic elastomer (TPE).

10. The method according to claim 8, wherein the nitrogen-based flame retardant comprises at least one selected from ammonium phosphate, ammonium carbonate, a triazine compound, melamine cyanurate, and a guanidine compound,
wherein the metal hydroxide comprises at least one selected from aluminum hydroxide and magnesium hydroxide, and
wherein the phosphorus-based flame retardant comprises at least one selected from organic phosphorus-based compounds including phosphate.

11. The method according to claim 8, wherein the thermally conductive filler of at least one of the low-hardness insulating heat-radiation layer and the high-heat-radiation insulating layer comprises at least one of carbon black, carbon nanotube, graphite, alumina, aluminum hydroxide, aluminum nitride, boron nitride, and a ceramic-carbon complex.

12. The method according to claim 8, wherein the process oil comprises at least one of a paraffin-based oil and a naphthen-based oil, and
wherein the process oil has a kinematic viscosity of 95 to 120 cSt at 40° C. and a flash point of 220 to 300° C.

13. The method according to claim 8, wherein at least one of the low-hardness insulating heat-radiation layer and the high-heat-radiation insulating layer further comprises a rubber,
wherein the rubber comprises at least one of an isoprene rubber (IR), a butadiene rubber (BR), a styrene-butadiene rubber (SBR), a polychloroprene rubber (CR), an acrylonitrile-butadiene rubber (NBR), an isoprene-isobutylene rubber (IIR), an ethylene-propylene rubber (EPR), a silicone rubber, a fluoro rubber, a urethane rubber, and an acrylic rubber, and
wherein the rubber is included in an amount of 5 to 200 parts by weight, based on 100 parts by weight of the thermoplastic elastomer (TPE).

14. The method according to claim 8, wherein the fourth step of sheeting is performed by:
independently or separately sheeting or forming the low-hardness insulating heat-radiation layer and the high-heat-radiation insulating layer, and hot-pressing the low-hardness insulating heat-radiation layer and the high-heat-radiation insulating layer to form a sheet; or
forming a sheet including the low-hardness insulating heat-radiation layer and the high-heat-radiation insulating layer at one time by a co-extrusion apparatus.
